(19) United States
(12) Patent Application Publication
(10) Pub. No.: US 2010/0061052 A1
(43) Pub. Date: Mar. 11, 2010

(54) ELECTRONIC APPARATUS

(75) Inventor: CHAO TSAI CHUNG, Taipei (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Pegatron Corporation, Taipei City (TW)

(21) Appl. No.: 12/553,916

(22) Filed: Sep. 3, 2009

(30) Foreign Application Priority Data
Sep. 5, 2008 (TW) 097134172

(51) Int. Cl. G06F 1/20; H05K 7/20

(52) U.S. Cl. 361/679.47; 361/697

(57) ABSTRACT

The invention discloses an electronic apparatus including a sealed housing, a heat-conducting component, and a fan. The heat-conducting component penetrates the sealed housing, and a fan is disposed in the sealed housing. The fan drives an air-flow, and the air-flow flows in the sealed housing and flows through the heat-conducting component.

### BACKGROUND OF THE INVENTION

1. Field of the Invention

The present invention relates to an electronic apparatus, and more particularly, to an electronic apparatus having a sealed housing.

2. Description of the Prior Art

The industrial computer means the computer not used in general consumer or commercial applications. The industrial computer is used not only in the industrial area, but also in other areas. With the rapid development of 3C and Internet, the industrial computer industry keeps enlarging its application area to the ordinary life. Additionally, the industrial computer product is usually used in poor using environment, so the industrial computer product needs the properties of resisting high temperature and low temperature, good heat-dissipation, dust-proof, and water-proof.

Because the industrial computer has higher dust-proof and water-proof requirements, the housing of the industrial computer has fewer and smaller ventilation holes. And the housing can even have no ventilation holes to avoid the dust or the water entering into the housing. Therefore, it is hard to exhaust the heat from the inside of the housing to the outside. In general, in order to meet the dust-proof and water-proof requirements, the design of the housing is considered better if the housing has fewer and smaller holes. The dust-proof and water-proof standard is usually marked by “IP” and two digits. For example, the first digit “6” of IP65 represents that the dust can be totally prevented from entering, and the second digit “5” of IP65 represents that there is no damage caused by water-washing. As to the dust-proof and water-proof standard IP65, a sealed housing is a better housing design solution. However, the sealed housing is easy to cause poor heat-dissipation, and the higher temperature in the housing will make the entire system unstable.

Furthermore, since it is rare to expand or upgrade the components of the industrial computer, the design of the components of the industrial computer will be closer to fully use the space in the housing. Therefore, the heat driven by the inner electronic components (e.g., the central processing unit, the Northbridge chip, the memory, and the hard disk) is easy to be cumulated in the housing. And, because the inner space of the housing is crowded and small space is left for the air-flow to flow, the thermal convection in the housing is not apparent and the heat will be locally cumulated in the housing. When more and more heat has been cumulated in the housing, the operation of the system is easy to be unstable or even crashed.

Instead of using a fan, the conventional industrial computer only uses the surface of the housing to passively dissipate the heat. Or, the main heat source can form a heat exchanger via heat pipes and fins to penetrating the system and finish the dust-proof and water-proof methods; the fan will be separated out of the system to dissipate the heat from the heat exchanger.

Please refer to FIG. 1, FIG. 1 illustrates a scheme diagram of an industrial computer 1 in the prior art. As shown in FIG. 1, the heat of main heating components of the industrial computer 1 (e.g., the central processing unit 13 and the Northbridge chip 15) can be conducted out of the sealed housing 10 via a heat pipe 14 adhered on the main heating components, so that the heat pipe 14 conducts the heat out from the sealed housing 10. Therefore, the main heating components such as the central processing unit 13 and the Northbridge chip 15 reach the heat-dissipating objective.

However, the above-mentioned design still has its drawbacks. In fact, the central processing unit and the Northbridge chip is only a part of heating components of the industrial computer, there are still other heating components in the housing. Although these heating components generate less heat than the main heating components, as time goes by, the temperature in the housing will be still increased. Intuitively, heat-conducting components can be disposed on each heating component, but the cost will be largely increased.

Therefore, how to provide a better heat-conducting design in an electronic apparatus (e.g., the industrial computer) having a sealed housing is the problem that the invention wants to solve.

### SUMMARY OF THE INVENTION

A scope of the invention is to provide an electronic apparatus having a sealed housing, and the electronic apparatus effectively exhaust the heat in the housing to lower the inner temperature.

According to a preferred embodiment of the invention, the electronic apparatus includes a sealed housing, a first heat-conducting component, and a first fan. The first heat-conducting component penetrates the sealed housing; the first fan disposed in the sealed housing. The first fan drives a first air-flow flowing in the sealed housing and through the first heat-conducting component.

The first heat-conducting component includes a first heat-conducting part and a second heat-conducting part, the first heat-conducting part is disposed in the sealed housing and the second heat-conducting part is disposed out of the sealed housing. The first fan is near the first heat-conducting part, so that the first air-flow driven by the first fan directly flow toward the first heat-conducting part.

The electronic apparatus further include a second fan disposed out of the sealed housing and near the second heat-conducting part, and the second fan drives a second air-flow to flow through the second heat-conducting part.

Additionally, the electronic apparatus further include a second heat-conducting component penetrating the sealed housing. The second heat-conducting component includes a third heat-conducting part and a fourth heat-conducting part. The third heat-conducting part is disposed in the sealed housing and contacts with an electronic component of the electronic apparatus, and the fourth heat-conducting part is disposed out of the sealed housing. The electronic component may be a central processing unit (CPU), a Northbridge chip, a Southbridge chip, or a memory. The second air-flow driven by the second fan will flow through the fourth heat-conducting part.

The embodiment of the invention uses the fan disposed in the sealed housing to bring the air-flow in the sealed housing, and the heat will be conducted out of the housing through the heat-conducting component penetrating the sealed housing. Therefore, the local heat cumulation in the sealed housing can be avoided, and the thermal convection will be strengthened to enhance the heat exchange efficiency between the heat and the outer cold air. Therefore, the invention provides a more effective heat exchange mechanism, so that the electronic apparatus having the sealed housing can be operated more stably.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1 illustrates a scheme diagram of the industrial computer in the prior art.

FIG. 2 illustrates a scheme diagram of the industrial computer in the first embodiment of the invention.

FIG. 3 illustrates a scheme diagram of the industrial computer in the second embodiment of the invention.

FIG. 4 illustrates a scheme diagram of the industrial computer in the third embodiment of the invention.

### DETAILED DESCRIPTION OF THE INVENTION

In general, the electronic apparatus with a sealed housing may be an industrial computer or an embedded computer having higher dust-proof and water-proof requirements. The International Protection Code (IP Code) is the specification of the dust-proof and water-proof level of the electronic apparatus made by International Electrotechnical Commission (IEC). The first digit after “IP” in the IP Code represents the dust-proof level, and the second digit after “IP” in the IP Code represents the water-proof level. If the digit is larger, the protection level will be larger. The sealed housing of the embodiment is defined as a sealed housing having the protection level of IP45 or higher than IP45. The industrial computer will be taken as an example of the electronic apparatus of the embodiment of the invention in the following explanation.

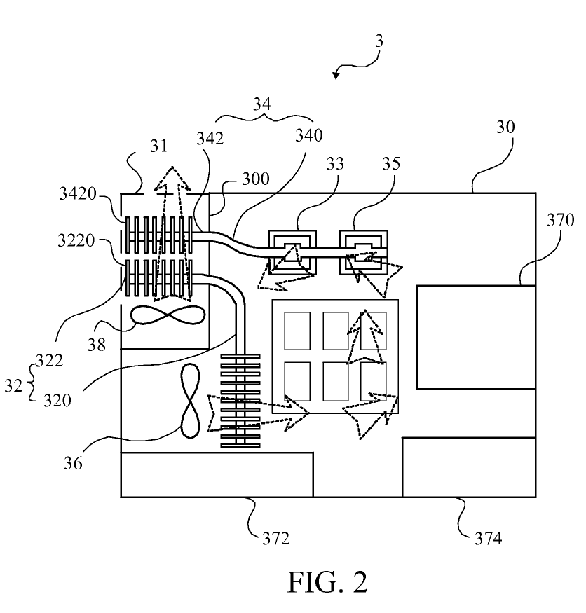

Please refer to FIG. 2, FIG. 2 shows a scheme diagram of an industrial computer 3 in the first embodiment of the invention. As shown in FIG. 2, the industrial computer 3 includes a sealed housing 30, a first heat-conducting component 32, a second heat-conducting component 34, and a first fan 36. The first fan 36 is mainly used to improve the inner thermal convection efficiency of the sealed housing 30 to bring the heat generated from the electronic components with smaller heating amount via air convection, and the first heat-conducting component 32 further conducts the heat of the inner air-flow to the outside of the sealed housing 30. The second heat-conducting component 34 is mainly used to enhance the thermal conduction efficiency of the electronic components with larger heating amount, so that most of the heat can be conducted to the outside of the sealed housing 30 via the thermal conduction effect.

As shown in FIG. 2, the first fan 36 is disposed in the sealed housing 30, and the first heat-conducting component 32 penetrates a side surface 300 of the sealed housing 30. The first heat-conducting component 32 includes a first heat-conducting part 320 and a second heat-conducting part 322, wherein the first heat-conducting part 320 is disposed in the sealed housing 30, and the second heat-conducting part 322 is disposed out of the sealed housing 30. The first fan 36 is near the first heat-conducting part 320, so that the inner air-flow (shown by a dotted-line arrow in FIG. 2) driven by the first fan 36 can directly flow toward the first heat-conducting part 320.

The inner air-flow (shown by the dotted-line arrow in FIG. 2) driven by the first fan 36 flows in the sealed housing 30 to bring the thermal convection, so that the air-flow near the electronic components with smaller heating amount or without being covered by any heat-conducting structure is brought to flow. For example, the heat of a hard disk 372, a CD-ROM drive 370, and a power supply 374 be conducted to the first heat-conducting component 32 via the thermal convection.

The first heat-conducting component 32 can be a heat pipe, and the heat of the first heat-conducting part 320 be rapidly conducted to the second heat-conducting part 322 due to the characteristic of the heat pipe. The flow that the first heat-conducting component 32 conducts the inner heat to the outer air is described as follows. At first, the inner air-flow will process a heat exchange with the first heat-conducting part 320; then, the heat will be conducted from the first heat-conducting part 320 to the second heat-conducting part 322; at last, the second heat-conducting part 322 will process a heat exchange with the outer cold air. Additionally, the second heat-conducting part 322 can further include a first fin 3220. The fin 3220 can increase the heat exchange area, and further increase the heat-dissipating efficiency of the second heat-conducting part 322.

As to the air-flow flowing in the sealed housing 30, because the temperature of the first heat-conducting part 320 is lower than the temperature in the sealed housing 30, therefore, the air near the first heat-conducting part 320 can process a heat exchange with the first heat-conducting part 320 to lower the air temperature, that is to say, the heat brought in by the thermal convection can be brought out. After the temperature-lowered air flows back to the heating electronic components, the heat exchange will be processed again. In this way, the inner air-flow (shown by the dotted-line arrow in FIG. 2) repeatly conducts the heat to the first heat-conducting component 32.

Furthermore, as shown in FIG. 2, the second heat-conducting component 34 of the industrial computer 3 penetrates the side surface 300 of the sealed housing 30. The second heat-conducting component 34 includes a third heat-conducting part 340 and a fourth heat-conducting part 342. The fourth heat-conducting part 342 is disposed out of the sealed housing 30; the third heat-conducting part 340 is disposed in the sealed housing 30 and contacts with a central processing unit 33 and a Northbridge chip 35 of the industrial computer 3. Additionally, the third heat-conducting part 340 can contact the electronic components with larger heating amount such as a Southbridge chip or a memory.

The third heat-conducting part 340 tightly contacts with the central processing unit 33 to directly conduct the heat to the fourth heat-conducting part 342, and the fourth heat-conducting part 342 can further process a heat exchange with the outer cold air. In general, the second heat-conducting component 34 can be a heat pipe, and the fourth heat-conducting part 342 can further include a second fin 3420. The second fin 3420 can increase the heat exchange area to further increase the heat-dissipating efficiency of the fourth heat-conducting part 342.

As shown in FIG. 2, the industrial computer 3 further includes a second fan 38 disposed out of the sealed housing 30 and near the second heat-conducting part 322. The second fan 38 drives an outer air-flow (shown by the dotted line in FIG. 2), and the outer air-flow flows through the second heat-conducting part 322 and the fourth heat-conducting part 342. The purpose of disposing the second fan 38 is to strengthen the heat exchange efficiency of the second heat-conducting part 322 and the fourth heat-conducting part 342 with the outer cold air. If no second fan 38 is disposed, the spacing between the second heat-conducting part 322 and the fourth heat-conducting part 342 out of the sealed housing 30 should be increased to avoid the heat accumulating in the space between the second heat-conducting part 322 and the fourth heat-conducting part 342 to ensure that the temperature of the air near the heat-conducting component is low enough.

It should be noticed that the industrial computer has higher dust-proof and water-proof requirements; therefore, there is no chink where the heat-conducting component penetrates the sealed housing. However, the sealed housing 30 in FIG. 2 does not include an outer housing 31 having several holes. The holes are used to let the outer air-flow driven by the second fan 38 flow out of the outer housing 31.

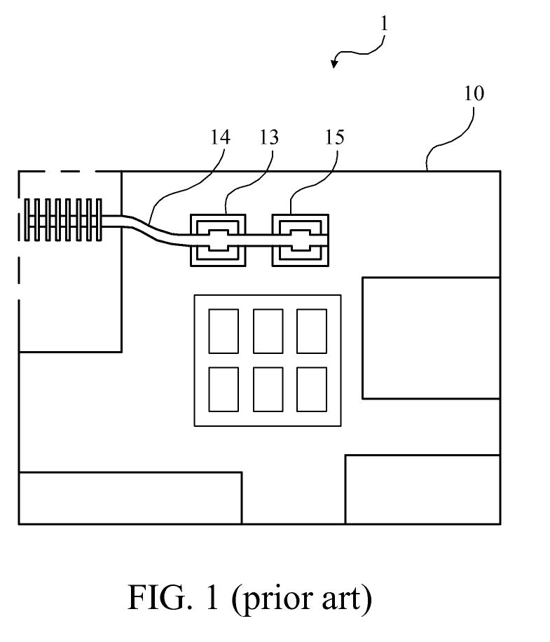

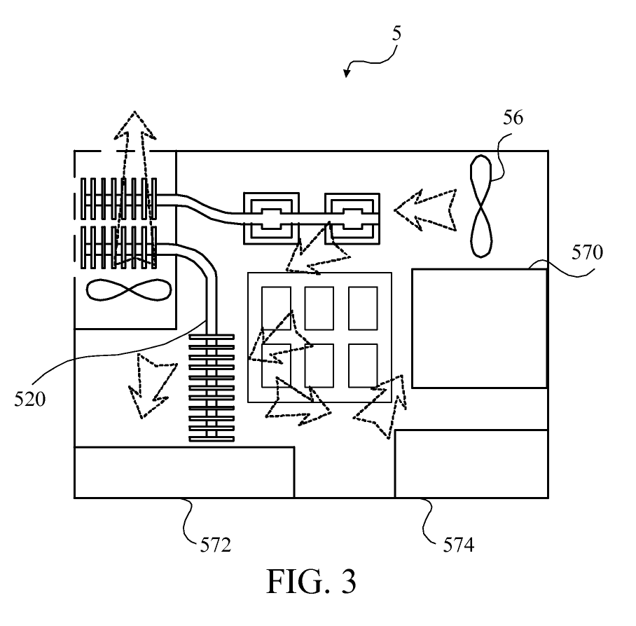

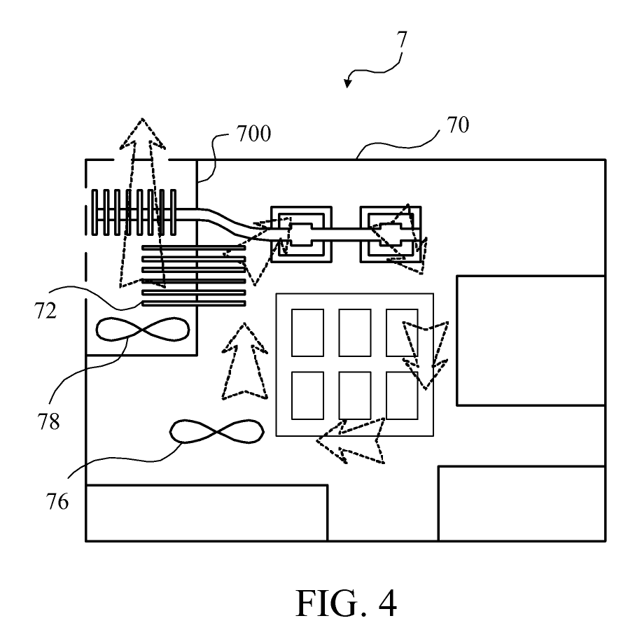

Besides the above-mentioned types, the industrial computer of the invention can still have other types, as shown in FIG. 3 and FIG. 4. Please refer to FIG. 3, FIG. 3 shows a scheme diagram of the industrial computer 5 in the second embodiment of the invention. Compared to FIG. 2, a first fan 56 of the industrial computer 5 shown in FIG. 3 is near a CD-ROM drive 570 instead of a first heat-conducting part 520. Of course, the first fan 56 can be also disposed near other electronic components (e.g., a hard disk 572 and a power supply 574). Compared to FIG. 1, the disposition of the first fan 56 in FIG. 3 can increase the mobility of the air near the electronic components without covering any heat-conducting component. Of course, there is no conflict between the disposition of the first fan 56 in FIG. 3 and the disposition of the first fan 36 in FIG. 2, the first fan 56 and the first fan 36 can be disposed at the same time to enhance the heat convection effect.

Please refer to FIG. 4, FIG. 4 shows a scheme diagram of an industrial computer 7 in the third embodiment of the invention. Compared to FIG. 2 and FIG. 3, the first heat-conducting component 72 of the industrial computer 7 shown in FIG. 4 includes several fins instead of a heat pipe. The fins are extended inward and outward from a side surface 700 of the housing 70, therefore, a first fan 76 and a second fan 78 drive air-flows flowing toward the fins to process the heat-conducting and heat-dissipating effect.

Besides the above-mentioned mechanical design (fans and heat-conducting components), a temperature sensor can be set on the mechanism of the industrial computer, and a temperature control circuit can be added into the circuit of the industrial computer. In this way, the first fan and the second fan can start or change their rotating speed according to different temperature conditions. For example, when the temperature in the sealed housing is lower, the first fan and the second fan can shut down or lower their rotating speed; when the temperature in the sealed housing is higher, the first fan and the second fan can start or increase their rotating speed. The design of temperature control can obtain a balance between the energy consumption and the heat-dissipating effect.

Compared with the prior art, this invention uses the fan disposed in the sealed housing to bring the air-flow in the sealed housing, and the heat will be conducted out of the housing through the heat-conducting component penetrating the sealed housing. Therefore, the local heat cumulation in the sealed housing can be avoided, and the thermal convection will be strengthened to enhance the heat exchange efficiency between the heat and the outer cold air. Therefore, the invention provides a more effective heat exchange mechanism, so that the electronic apparatus having the sealed housing can be operated more stably.

Although the present invention has been illustrated and described with reference to the preferred embodiment thereof, it should be understood that it is in no way limited to the details of such embodiment but is capable of numerous modifications within the scope of the appended claims.

What is claimed is:

1. An electronic apparatus, comprising:
1) a sealed housing;
2) a first heat-conducting component penetrating the sealed housing; and
3) a first fan disposed in the sealed housing, the first fan driving a first air-flow flowing in the sealed housing and through the first heat-conducting component.

2. The electronic apparatus of claim 1, wherein the first heat-conducting component comprises a first heat-conducting part and a second heat-conducting part, the first heat-conducting part is disposed in the sealed housing and the second heat-conducting part is disposed out of the sealed housing.

3. The electronic apparatus of claim 2, wherein the first fan is near the first heat-conducting part, so that the first air-flow driven by the first fan flows toward the first heat-conducting part.

4. The electronic apparatus of claim 2, further comprising a second fan disposed out of the sealed housing and near the second heat-conducting part, the second fan generating a second air-flow to flow through the second heat-conducting part.

5. The electronic apparatus of claim 4, further comprising a second heat-conducting component penetrating the sealed housing, the second heat-conducting component comprising a third heat-conducting part and a fourth heat-conducting part, the third heat-conducting part being disposed in the sealed housing and contacting with at least one electronic component of the electronic apparatus, the fourth heat-conducting part being disposed out of the sealed housing.

6. The electronic apparatus of claim 5, wherein the electronic component is a central processing unit (CPU), a Northbridge chip, or a Southbridge chip.

7. The electronic apparatus of claim 5, wherein the second air-flow driven by the second fan flows through the fourth heat-conducting part.

8. The electronic apparatus of claim 2, wherein the first heat-conducting part comprises a fin.

9. The electronic apparatus of claim 2, wherein the first heat-conducting component is hung in the sealed housing.

10. The electronic apparatus of claim 1, wherein the first heat-conducting component comprises a heat pipe.

11. The electronic apparatus of claim 1, wherein the first heat-conducting component comprises a fin.

12. The electronic apparatus of claim 1, wherein the sealed housing helps the electronic apparatus reach a protection level of IP45 or higher than IP45.
